(19) United States
(12) Patent Application Publication
(10) Pub. No.: US 2025/0067815 A1
(43) Pub. Date: Feb. 27, 2025

(54) METHOD AND DEVICE WITH SHORT RESISTANCE ESTIMATION AND DETECTION

(71) Applicant: Samsung Electronics Co., Ltd., Suwon-si (KR)

(72) Inventors: Sagar BHARATHRAJ, Bengaluru (IN); Shashishekara Parampalli ADIGA, Bengaluru (IN)

(73) Assignee: Samsung Electronics Co., Ltd., Suwon-si (KR)

(21) Appl. No.: 18/797,418

(22) Filed: Aug. 7, 2024

(30) Foreign Application Priority Data
Aug. 22, 2023 (IN) 202341056340
Nov. 22, 2023 (KR) 10-2023-0163189

(51) Int. Cl. G01R 31/52; G01R 31/378; G01R 31/3835; H01M 10/42

(52) U.S. Cl. CPC G01R 31/52; G01R 31/378; G01R 31/3835; H01M 10/4285

(57) ABSTRACT

Provided is a method of estimating a short resistance of a target battery associated with a battery-driven device. The method includes: determining voltage values of the target battery within a time period during a charging or discharging state of the target battery, wherein the time period is associated with a constant resistance value within the target battery; comparing the voltage values with reference voltage values associated with a reference battery; based on the comparing, determining, for the pre-defined time period, a magnitude of a voltage deviation of the target battery with respect to the reference battery; detecting a short circuit in the target battery based on the determined magnitude of the voltage deviation; and estimating the short resistance associated with the short circuit of the target battery based on the constant resistance value and the magnitude of the voltage deviation.

### CROSS-REFERENCE TO RELATED APPLICATIONS

This application claims the benefit under 35 USC § 119(a) of Indian Patent Application No. 202341056340 filed on Aug. 22, 2023, in the Indian Patent Office, and Korean Patent Application No. 10-2023-0163189 filed on Nov. 22, 2023, in the Korean Intellectual Property Office, the entire disclosures of which are incorporated herein by reference for all purposes.

### BACKGROUND

### 1. Field

The present disclosure generally relates to the field of batteries, and more particularly relates to methods and systems with estimation of short resistance of a battery associated with a battery-enabled device.

### 2. Description of Related Art

Batteries play a fundamental role in supplying power to electronic devices. Batteries energize electronic circuits and components of electronic devices. Over time, batteries have evolved to meet the diverse needs of electronic devices. Generally, electronic devices such as smartphones, laptops, and wearables have an integrated battery. The battery may be discharged during use and may be recharged thereafter using an external power source.

Lithium-ion (Li-ion) batteries are one example of a rechargeable battery (or a secondary battery). Li-ion batteries are considered to be cost-effective and environmentally friendly. Li-ion batteries, which are generally rechargeable, have high energy density and long lifespan and are widely used in various electronic devices. However, a short circuit may happen in a rechargeable battery due to unintentional electrical contact between a positive terminal and a negative terminal of the rechargeable battery.

FIG. 1 shows an example of unintentional electrical contact in a battery 102 leading to a short circuit. The battery 102 may be charged by an external power source 104. Further, the short circuit is unintentionally caused due to the electrical contact (a conductive path) between the positive (+) terminal and the negative (−) terminal of the battery 102. In short circuit condition, resistance of the electrical contact between the positive terminal and the negative terminal of the battery 102 will be denoted as a short resistance Rₛₕ. A higher value of Rₛₕ permits a low amount of current to flow through the short circuit, whereas a lower value of Rₛₕ permits a high amount of current to flow through the short circuit. Thus, for the lower value of Rₛₕ, a large amount of thermal energy is released because of the high amount of current flow between the positive terminal and the negative terminal. Further, the short circuit may cause additional chain reactions, like electrolyte decomposition, and may result in loss of active material. As a result, the temperature of the battery 102 may be increased. Therefore, the short circuit may result in a rapid discharge of energy, causing excessive heat buildup and may potentially lead to damage, failure, or even cause fire in the rechargeable battery.

Detection of short circuits in early stages as well as estimating a short resistance is important to prevent damage or failure of the battery. Catastrophes (e.g., fire) in batteries may be prevented if short circuits are detected and estimated very early on (200 ohms (Ω) and above). However, the influence of an early-stage short circuit, such as a soft short (e.g., 200Ω) on the battery is very feeble and therefore difficult to detect. Moreover, it is very difficult to properly distinguish early-stage short signatures from signatures of a healthy battery. Conventional techniques for short prediction are only useful for predicting a late-stage short circuit (100Ω and below). Even in the conventional techniques, the accuracy of short detection is less than around 85%.

### SUMMARY

This summary is provided to introduce a selection of concepts, in a simplified format, that are further described in the detailed description of the disclosure. This summary is neither intended to identify key or essential inventive concepts of the invention nor is it intended for determining the scope of the disclosure.

According to an example, a method of estimating a short resistance of a target battery configured to provide power to a device is performed by one or more processors and includes: determining voltage values of the target battery within a time period during a charging or discharging state of the target battery, wherein the time period is associated with a constant resistance value within the target battery; comparing the voltage values with reference voltage values associated with a reference battery; based on the comparing, determining, for the pre-defined time period, a magnitude of a voltage deviation of the target battery with respect to the reference battery; detecting a short circuit in the target battery based on the determined magnitude of the voltage deviation; and estimating the short resistance associated with the short circuit of the target battery based on the constant resistance value and the magnitude of the voltage deviation.

The determining of the magnitude of the voltage deviation may include: determining a first curve based on the voltage values determined within the time period; obtaining a second curve based on the reference voltage values associated with the reference battery; and calculating the magnitude of the voltage deviation based on a comparison of the first curve with the second curve.

The detecting of the short circuit in the target battery may include: comparing the magnitude of the voltage deviation with a voltage threshold value; and based on determining that the magnitude of the voltage deviation is greater than the voltage threshold value, detecting the short circuit in the target battery.

The short resistance may be proportional to a ratio of the magnitude of the voltage deviation and the constant resistance value.

The determining of the voltage values may include: determining a current voltage of the target battery; and determining the voltage values within the time period based on the current voltage reaching a pre-defined battery voltage.

The time period may be associated with timestamps, each voltage value may correspond to a product of a total resistance and a total current within the target battery at a time of a corresponding timestamp, and each reference voltage value may correspond to a product of a total resistance and a total current within the reference battery at a time of a corresponding timestamp.

The target battery may comprise, or be comprised in, a rechargeable lithium-ion (Li-ion) battery.

The method may further include: comparing the estimated short resistance with a short resistance threshold value; and based on determining that the estimated short resistance is less than the short resistance threshold value, initiating a remediation action.

The remediation action may include rendering an alert or controlling use of the battery.

The estimating of the short resistance may include calculating, using an electrochemical-thermal model, the short resistance utilizing the constant resistance value and the magnitude of the voltage deviation of the voltage values with respect to the reference voltage values.

The constant resistance value, the time period, and the reference voltage values may be pre-stored in a memory associated with the battery-enabled device.

In another general aspect, a system for estimating a short resistance of a target battery includes: one or more processors; memory storing instructions configured to cause the one or more processors to: determine voltage values of the target battery for a time period during a charging or discharging state of the target battery, wherein the time period is associated with a constant resistance value within the target battery; compare the voltage values with reference voltage values associated with a reference battery, and based on the comparing, for the time period, determine a magnitude of a voltage deviation of the target battery with respect to the reference battery; detect a short circuit in the target battery based on the determined magnitude of the voltage deviation; and estimate the short resistance of the target battery based on the constant resistance value and the magnitude of the voltage deviation.

The instructions may be further configured to cause the one or more processors to: determine a first curve based on the voltage values determined within the time period, obtain a second curve based on the reference voltage values associated with the reference battery, and calculate the magnitude of the voltage deviation based on a comparison of the first curve with the second curve.

The instructions may be further configured to cause the one or more processors: compare the magnitude of the voltage deviation with a voltage threshold value, and based on determining that the magnitude of the voltage deviation is greater than the voltage threshold value, detect the short circuit in the target battery.

The instructions may be further configured to cause the one or more processors to: determine a current voltage associated with the target battery, and determine the voltage values for the time period when the current voltage reaches a pre-defined battery voltage.

The time period may be associated with timestamps, each voltage value may correspond to a product of a total resistance and a total current within the target battery at a time of a corresponding timestamp, and each reference voltage value may correspond to a product of a total resistance and a total current within the reference battery at a time of a corresponding timestamp.

The target battery may comprise, or be comprised in, a rechargeable lithium-ion (Li-ion) battery.

The instructions may be further configured to cause the one or more processors to: compare the estimated short resistance with a short resistance threshold value, and based on determining that the estimated short resistance is less than the short resistance threshold value, display an alert on a display unit of the battery-enabled device.

The instructions may be further configured to cause the one or more processors to calculate, using an electrochemical-thermal model, the short resistance utilizing the constant resistance value and the magnitude of the voltage deviation in the voltage values with respect to the reference voltage values.

In yet another general aspect, a battery-enabled device includes: a memory; and a processor communicatively coupled with the memory, wherein the processor is configured to: determine voltage values of a target battery for a defined time period, having a constant resistance value within the target battery, obtain reference voltage values corresponding to the defined time period, the reference voltages associated with a reference battery, determine a magnitude of a voltage deviation between the voltage values and the reference voltage values, detect a short circuit in the target battery based on the determined magnitude of the voltage deviation, and estimate a short resistance of the target battery based on the constant resistance value and the magnitude of the voltage deviation.

To further clarify the advantages and features of the present disclosure, a more particular description of the disclosure will be rendered by reference to specific examples thereof, which are illustrated in the appended drawings. It is appreciated that these drawings depict only typical examples of the disclosure and are therefore not to be considered limiting its scope. The disclosure will be described and explained with additional specificity and detail with the accompanying drawings.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 illustrates an example of a battery having a short circuit;

FIG. 2A illustrates an example of a battery-enabled device for estimating a short resistance of a target battery, according to one or more embodiments;

FIG. 2B illustrates an example of the modules illustrated in FIG. 2A, according to one or more embodiments;

FIG. 3 illustrates an example of voltage values and reference voltage values over a pre-defined time period, according to one or more embodiments;

FIG. 4 illustrates an example of relative voltage deviation for a target battery and a reference battery over a pre-defined time period, according to one or more embodiments;

FIG. 5 illustrates an example of estimating a short resistance of a battery of a battery-enabled device, according to one or more embodiments; and

FIG. 6 illustrates an example implementation of a hardware configuration, according to one or more embodiments.

Throughout the drawings and the detailed description, unless otherwise described or provided, the same or like drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

As used herein, the term “battery” refers to a rechargeable battery (or a secondary battery). The terms “electronic device”, “device”, “battery-based device”, and “battery-enabled device” are used interchangeably throughout this description.

As used herein, the term “target battery” refers to battery of a battery-based device in which a short circuit is to be detected and a short resistance for the short circuit is to be estimated.

As used herein, the term “reference battery” corresponds to a healthy battery, i.e., a battery without any degradation. For instance, a battery when manufactured and used for the first time within a device may be a reference battery. After predetermined usages of a battery, the health of the battery is automatically degraded based on the inherent characteristics of one or more electrochemical cells of the battery. In a non-limiting example, a battery X of a mobile device may correspond to the healthy battery when the battery X is manufactured and used for the first time. After usage of the rechargeable battery, the health of the battery is automatically degraded, and the persistent short circuit may occur due to an unintentional connection between the positive terminal and the negative terminal.

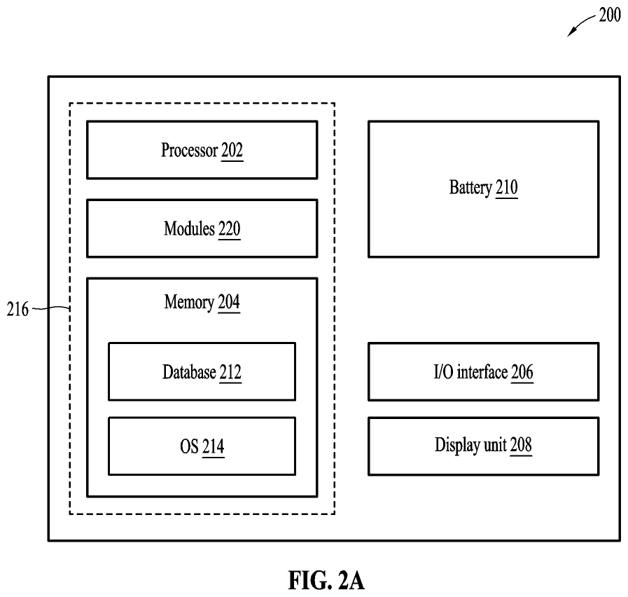

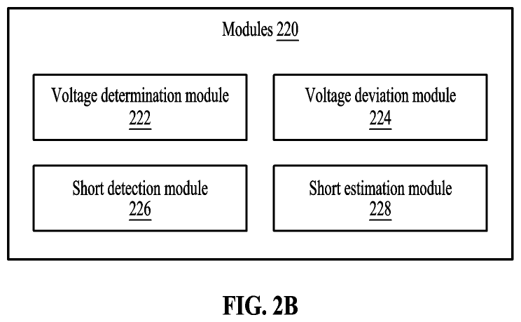

FIG. 2A illustrates an example of a battery-enabled device 200 for estimating a short resistance of a target battery, according to one or more embodiments. The term “target battery” refers to a battery associated with the battery-enabled device 200, e.g., battery 210.

The device 200 includes one or more processors 202 (hereinafter, referred to as “processor”), a memory 204, an input/output (I/O) interface 206, a display unit 208, and the battery 210. The memory 204 includes a database 212 and an operating system (OS) 214 (components of which may execute on the processor 202, e.g., a kernel). The device 200 further includes one or more modules 220. In some examples, the I/O interface 206 may include the display unit 208. The processor 202, the memory 204, the battery 210, the display unit 208, and the I/O interface 206 may be communicatively coupled with each other. In a non-limiting example, the battery-enabled device 200 may correspond to a smartphone, a mobile, a tablet, a computer, a laptop, a car, a motorbike, a vacuum cleaner, or any other electronic devices utilizing rechargeable batteries.

In some examples, the device 200 may include a system 216 including the processor 202, the modules 220, and the memory 204, the system 216 being configured to estimate the short resistance associated with the battery 210. It is appreciated that the battery 210 may be interchangeably referred to as a “target battery”. In some examples, the system 216 may be integrated within the device 200. In some examples, one or more components of the system 216 may be implemented in a cloud-based architecture or on a physical server (not shown).

According to an example, the processor 202 may be operatively coupled to the memory 204 and/or the modules 220 for processing, executing, or performing a set of operations. In an example, the processor 202 may include at least one data processor for executing processes in a virtual storage area network. The processor 202 may include specialized processing units such as integrated system (bus) controllers, memory management control units, floating point units, graphics processing units, digital signal processing units, etc. In an example, the processor 202 may include a central processing unit (CPU), a graphics processing unit (GPU), or both. The processor 202 may be one or more general processors, digital signal processors, application-specific integrated circuits, field-programmable gate arrays, servers, networks, digital circuits, analog circuits, combinations thereof, or other now known or later developed devices for analyzing and processing data. The processor 202 may execute one or more instructions, such as code generated manually (i.e., programmed) to perform one or more operations disclosed herein.

According to an example, the processor 202 may operate in conjunction with the modules 220 for performing predetermined operations. The term “module” or “modules” used herein may imply a unit including, for example, one of hardware, software (in the form of computer executable instructions), and firmware or a combination of two or more thereof. The “module” may be interchangeably used with a term such as logic, a logical block, a component, and the like. The “module” may be a minimum device component for performing one or more functions or may be a part thereof. In some examples, the processor 202 may control the modules 220 to execute a predetermined set of operations described in the disclosure.

In some examples, the modules 220 may be configured to perform designated functions in conjunction with the memory 204 and the processor 202. In some examples, the memory 204 may be communicatively coupled to the processor 202. In some examples, the modules 220 may be included within the memory 204. The memory 204 may be configured to store data, and instructions executable by the processor 202.

In some examples, the modules 220 may include a set of instructions that may be executed to cause the system 216 to perform any one or more of the methods disclosed herein. The modules 220 may be configured to perform the operations of the present disclosure using the data stored in the memory 204, as discussed throughout this disclosure. In an example, the modules 220 may be hardware units that may be outside the memory 204.

According to an example, the memory 204 may include any non-transitory computer-readable medium known in the art including, for example, volatile memory, such as static random-access memory (SRAM) and dynamic random-access memory (DRAM), and/or non-volatile memory, such as read-only memory (ROM), erasable programmable ROM, flash memories, hard disks, optical disks, and magnetic tapes. The memory 204 is communicatively coupled with the processor 202 to store bitstreams or processing instructions for completing the process. Further, the memory 204 may include the OS 214 for performing one or more tasks of the battery-enabled device 200, as performed by a generic operating system in the communications domain or the standalone device. In an example, the memory 204 may include the database 212 configured to store the information as required by the modules 220 and the processor 202 to perform one or more functions for estimating the short resistance of the battery 210 of the battery-enabled device 200, as discussed throughout the disclosure.

The memory 204 may be operable to store instructions executable by the processor 202. The functions, acts, or tasks illustrated in the figures or described may be performed by the processor 202, in conjunction with the modules 220, for executing the instructions stored in the memory 204. The functions, acts, or tasks are independent of a predetermined type of instruction set, storage media, processor, or processing strategy and may be performed by software, hardware, integrated circuits, firmware, micro-code, and the like, operating alone or in combination. Likewise, processing strategies may include multiprocessing, multitasking, parallel processing, and the like.

In an example, the memory 204 may be configured to store the information as required by the modules 220 and/or the processor 202 to perform the methods described herein.

According to an example, the battery 210 may be a rechargeable battery. The battery-enabled device 200 may include one or more batteries 210 to fulfill the electrical energy required by the battery-enabled device 200. The battery 210 may be a rechargeable lithium-ion (Li-ion) battery including one or more electrochemical cells. Each of the one or more electrochemical cells converts chemical energy into electrical energy through electrochemical reactions. During charging of the battery 210, an external power source (not shown) may be connected to the device 200, in particular the battery 210, to cause a flow of electrons from a positive electrode (i.e., the positive terminal) to a negative electrode (i.e., the negative terminal) in the one or more electrochemical cells. Simultaneously, ions migrate from the negative electrode to the positive electrode to complete the electrochemical reactions.

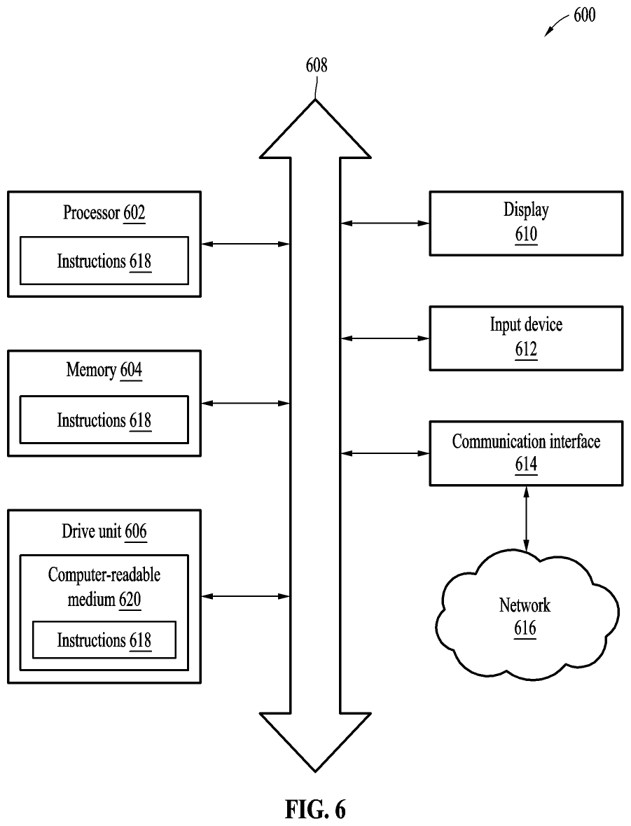

According to an example, the I/O interface 206 refers to hardware or software components that enable data communication between the battery-enabled device 200 and any other devices or systems. The I/O interface 206 serves as a communication medium for exchanging information, commands, or data with the other devices or systems. The I/O interface 206 is described in later with reference to FIG. 6's communication interface 614.

According to an example, the display unit 208 may refer to a display screen, a monitor, a graphical user interface, or the like. The display unit 208 may be an output device that visually presents information to a user. The display unit 208 may form an integral part of various electronic devices, including computers, smartphones, mobiles, user devices, tablets, televisions, cars, and the like. The display unit 208 may be configured to render visual content and provide a graphical user interface for interacting with the battery-enabled device 200. The display unit 208 is described with reference to the display 610 of FIG. 6.

FIG. 2B illustrates an example of modules 220 in FIG. 2A. The modules 220 include a voltage determination module 222, a voltage deviation module 224, a short detection module 226, and a short estimation module 228.

In some examples, the modules 220 may utilize data stored in the database 212 of the memory 204 for performing corresponding operations. The database 212 may store executable instructions and/or data generated when the modules 220 execute one or more operations.

Referring to FIGS. 2A and 2B, the system 216 may be configured to estimate a short resistance of a target battery, e.g., the battery 210 of the battery-enabled device 200. The battery 210 may be a rechargeable Li-ion battery. The terms “battery 210” and “target battery 210” are used interchangeably in places.

The processor 202, in conjunction with the voltage determination module 222, may be configured to determine voltage values for the battery 210 for a pre-defined time period (“pre-defined” means defined before being used). In some examples, the processor 202 may be configured to determine the voltage values during a charging state of the battery 210 (when the device 200 is being charged). In some examples, the processor 202 may be configured to determine the voltage values during a discharging state of the battery 210 (when the device 200 is being discharged or is in use).

In some examples, the pre-defined time period is associated with a constant resistance value within the target battery 210. In some examples, the processor 202 may be configured to determine the voltage values when the voltage of the target battery 210 reaches a pre-defined battery voltage (e.g., a “trigger” voltage). That is, the determination of the voltage values may be triggered when the voltage of the target battery 210 reaches the pre-defined battery voltage (trigger voltage). In some examples, the pre-defined time period and the pre-defined battery voltage may be stored in the memory 204, such as, in the database 212 within the memory 204. In some examples, the pre-defined battery voltage may be any suitable battery voltage of the target battery 210.

In some examples, to determine the voltage values, the processor 202 may be configured to determine a current voltage of the target battery 210, i.e., a real-time voltage of the target battery 210. The processor 202 may further be configured to initiate the determination of the voltage values (for the pre-defined time period) when the current voltage of the target battery 210 reaches the pre-defined battery voltage (trigger voltage). In some examples, the processor 202 may be configured to automatically initiate the determination based on determining that a preset number of charging cycles have occurred and/or based upon receiving a user input from a user.

In a non-limiting example, the processor 202 may be configured to determine the voltage values when the voltage of the target battery 210 is determined to reach 50% (i.e., the pre-defined trigger battery voltage) of the batteries baseline (e.g., full) voltage. Here, 50% is only an example; other values may be used. The voltage values may be determined for 250 seconds (i.e., the pre-defined time period). During the pre-defined time period, the battery 210 may be associated with a constant resistance (CR) of “K” ohms, i.e., CR=K Ω. In some examples, a value of the constant resistance may be stored in the memory 204, such as, in the database 212 within the memory 204.

In some examples, the pre-defined time period may correspond to a predetermined time period within a month or a year (relative to the creation of the battery) when the determination may be initiated. For example, the processor 202, in conjunction with the voltage determination module 222, may be configured to initiate the determination during any of 3rd to 9th of every month at the time of charging of the battery 210.

The processor 202, in conjunction with the voltage deviation module 224, may be configured to compare the voltage values with reference voltage values associated with a reference battery. As described above, the reference battery may be a healthy battery, e.g., a factory-condition battery, a modeled ideal battery, etc. The reference voltage values may be voltage values of the reference battery over the pre-defined time period. In some examples, the reference voltage values may be stored in the memory 204, such as in the database 212.

In some examples, the determining of the voltage values (reference and target/non-reference) by the processor 202 may include capturing timestamps of the respective voltage values within the pre-defined time period of the determined voltage values. That is, the pre-defined time period may have, associated therewith, timestamps of respectively corresponding voltage values (each timestamp representing a time of a corresponding voltage value).

In some examples, each voltage value corresponds to a product of a total resistance and a total current within the target battery 210 at a corresponding timestamp. In some examples, each reference voltage value corresponds to a product of a total resistance and a total current within the reference battery at a corresponding timestamp of the plurality of timestamps.

In some examples, the target battery 210 may have a short circuit with a short resistance of Rₛₕ and a leakage current Iₛₕ.

In some examples, the total resistance within the reference battery may be equivalent to the constant resistance (CR), i.e., K Ω. The total resistance within the target battery may be equivalent to a sum of the CR and the short resistance Rₛₕ.

In some examples, the total current within the reference battery may be equivalent to a normal current Iₙₒᵣₘₐₗ. The reference battery may be assumed to have no leakage current and so its normal current is also its total current. In some examples, the total current within the target battery may be equivalent to a sum of the normal current Iₙₒᵣₘₐₗ and the leakage current Iₛₕ.

The processor 202, in conjunction with the voltage deviation module 224, may be configured to determine a magnitude of a voltage deviation associated with the target battery 210 with respect to the reference battery (i.e., a target-reference voltage deviation). The magnitude of the voltage deviation may be determined for the pre-defined time period based on comparing the voltage values with the reference voltage values.

In some examples, a magnitude of the target-reference voltage deviation may be determined. The processor 202 may be configured to determine a first curve based on the voltage values of the target battery determined within the pre-defined time period. For instance, the processor 202 may be configured to determine variations in the voltage values within the pre-defined time period. The first curve may represent variations in the voltage values over the pre-defined time period.

In some examples, the processor 202 may be configured to obtain a second curve relating to the reference voltage values associated with the reference battery. The second curve may represent variations in the reference voltage values over the pre-defined time period. In some examples, the second curve may be stored in the memory 204, such as, in the database 212.

In some examples, the processor 202 may be configured to calculate the magnitude of the voltage deviation based on a comparison of the first curve and the second curve. In some examples, the magnitude of the voltage deviation is proportional to the constant resistance value and the short resistance.

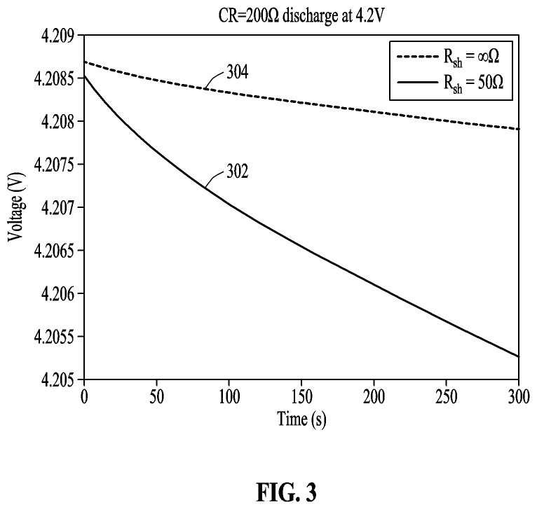

FIG. 3 illustrates an example of voltage values and reference voltage values over a pre-defined time period. The pre-defined time period may be considered as 300 seconds. The CR may be considered as K=200Ω. The reference battery may have no short circuit, and hence, the short resistance for the reference battery may be considered as Rₛₕ=∞Ω. The short resistance for the target battery 210 may be considered as Rₛₕ=50Ω. The pre-defined battery voltage when the constant resistance based determination is initiated may be 4.2 volts (V). The graphical representation shows a first curve 302 and a second curve 304. The first curve 302 represents the voltage values over the pre-defined time period. The second curve 304 represents the reference voltage values over the pre-defined time period.

As shown in FIG. 3, the first curve 302 (target) deviates from the second curve 304 (reference). In some examples, the deviation may be due only (or primarily) to the presence of the short resistance Rₛₕ in the target battery 210. The magnitude of the deviation may be proportional to the constant resistance value CR=K Ω and the short resistance Rₛₕ in the target battery 210 (e.g., proportional their ratio). In some examples, the graphical representation may be obtained based on an electrochemical-thermal reduced order model (ECT-ROM).

The magnitude of the voltage deviation may be determined based on a distance between the first curve corresponding to the target battery 210 and the second curve corresponding to the reference battery. In some examples, the magnitude of the deviation may be determined in consideration of the distance (difference) between an end value of the first curve and a corresponding end value of the second curve.

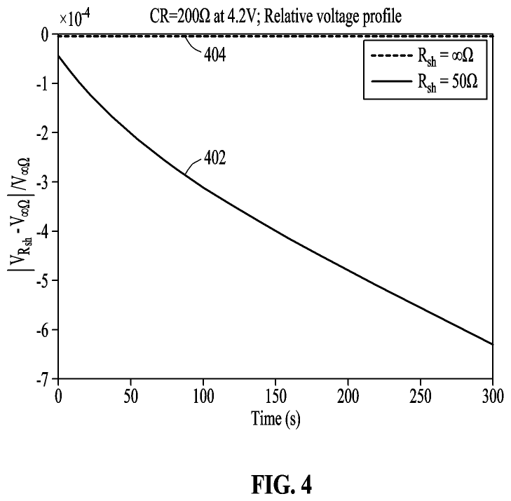

FIG. 4 illustrates an example of relative voltage deviation for the target battery 210 and the reference battery over a pre-defined time period, according to one or more embodiments. The pre-defined time period may be 300 seconds, as an example. The CR may be K=200Ω, as an example. The short resistance for the reference battery may be considered as Rₛₕ=∞Ω. The short resistance for the target battery 210 may be considered as Rₛₕ=50Ω, as an example. The pre-defined battery voltage when the constant resistance-based determination is initiated may be 4.2 V. FIG. 4 shows a first curve 402 and a second curve 404. The first curve 402 corresponds to the voltage values of the target battery over the pre-defined time period, and the second curve 404 relates to the reference voltage values over the pre-defined time period. The magnitude of the deviation may be proportional to CR=K Ω and the short resistance Rₛₕ based on Equation 1.

$$( [ {V}_{{R}_{sh}} - {V}_{∞Ω} ] / {V}_{∞Ω} ) α [ K / {R}_{sh} ] \qquad Equation 1$$

In some examples, the processor 202, in conjunction with the short detection module 226, may be configured to detect a short circuit (or the presence of a short circuit) in the target battery 210 based on the determined magnitude of the voltage deviation. In some examples, to detect the short circuit, the processor 202 may be configured to compare the magnitude of the voltage deviation with a voltage threshold value. In some examples, the voltage threshold value may be stored in the memory 204, such as, in the database 212 within the memory 204.

In some examples, the processor 202, in conjunction with the short detection module 226, may be configured to detect the short circuit in the target battery 210 upon determining that the magnitude of the voltage deviation is greater than the voltage threshold value. In some examples, the processor 202, in conjunction with the short detection module 226, may be configured to detect absence of the short circuit in the target battery 210 upon determining that the magnitude of the voltage deviation is less than the voltage threshold value. In some examples, to compare the magnitude of the voltage deviation with the voltage threshold value, the slope of the first curve over a portion of the time period may be compared with a slope threshold value. In some examples, the threshold value may be −1e06*. In some examples, the subset of time period may be a preset percentage of the pre-defined time period. In a non-limiting example, in the case where the pre-defined time period is 5 minutes, then the subset of time period may be 2 minutes (40%).

In some examples, the calculation/operation for determining the magnitude of the deviation is performed when pre-defined reference operating conditions arise based on the voltage values (target battery) with respect to the reference voltage values. The predetermined reference operating conditions may remain the same during the determination of the voltage values and the determination of the reference voltage values. The reference operating conditions may be one or more conditional parameters such as, but not limited to, a temperature condition, a constant resistance condition, a charging or discharging window, a battery level at which the charging or discharging is initiated, etc. However, any condition associated with potential battery shorting may be used. A condition is not required, and short checking may be performed at intervals, randomly, upon manual request, etc.

In some examples, the processor 202, in conjunction with (e.g., while executing) the short estimation module 228, may be configured to estimate the short resistance of the target battery based on the CR value and the magnitude of the voltage deviation. In some examples, to estimate the short resistance of the battery 210, the processor 202, in conjunction with/executing the short estimation module 228, is configured to calculate, using an electrochemical-thermal model, the short resistance based on the constant resistance value and the magnitude of the voltage deviation of the target battery voltage values relative to the reference voltage values.

According to an example, the electrochemical-thermal model may be configured to estimate the short resistance as follows. In CR-based measurements of voltage values, the voltage V and the current I should follow the requirement expressed by Equation 2.

$$V / I = K Ω \qquad Equation 2$$

In the case of a short circuit within the target battery 210, a leakage current Iₛₕ and a short resistance Rₛₕ may be present within the target battery 210. The leakage current Iₛₕ may be equal to V/Rₛₕ.

In order to maintain the CR as well as to sustain the leakage current Iₛₕ, the voltage associated with the target battery 210 depends on K*I_{new}, where I_{new} is a new battery current as expressed by Equation 3.

$${I}_{new} = I + {I}_{sh} or {I}_{new} = I + V / {R}_{sh} \qquad Equation 3$$

The voltage may be determined based on electrochemical a model of physics and may depend on the applied current input, i.e., V=f(I). In the case of presence of a short circuit, based on Equation 3, the new battery current may be expressed by Equation 4.

$${I}_{new} = I + {I}_{sh} = V / K + V / {R}_{sh} \qquad Equation 4$$

Accordingly, a new voltage V_{new} may be based on Equation 5.

$${V}_{new} ∝ K \times ( \frac{V}{K} + \frac{V}{{R}_{sh}} ) \qquad Equation 5$$

Further, the short resistance may be determined based on Equation 6 and Equation 7.

$$\frac{{V}_{new}}{V} ∝ ( 1 + \frac{K}{{R}_{sh}} ) - \to \frac{{V}_{new}}{V} - 1 = {V}^{′} ∝ \frac{K}{{R}_{sh}} \qquad Equation 6$$

$$\frac{{dV}^{′}}{d t} = a ( b + \frac{K}{{R}_{sh}} ) \qquad Equation 7$$

In Equation 7, V′ is the relative voltage, and a and b refer to the present parameters for the target battery 210.

In some examples, the processor 202, in conjunction with the short estimation module 228, may be configured to compare the estimated short resistance with a short resistance threshold value. In some examples, the short resistance threshold value may be stored in the memory 204, such as, in the database 212 within the memory 204.

In some examples, the processor 202 may be configured to display an alert on the display unit 208 of the battery-enabled device 200 when the estimated short resistance is less than the short resistance threshold value. The alert may be indicative of the estimated short resistance. By displaying the alert on the display unit 208 of the battery-enabled device 200, a user of the battery-enabled device 200 may be notified in advance that the battery 210 has a short circuit. The alert may further indicate that the battery 210 should be checked at a service center to avoid any damage. Other remediation actions may be triggered in response to the determination of a short, for example, powering down a device, transmitting messages, deactivating the battery from among batteries in a bank, etc.

In a non-limiting example, a short resistance Rₛₕ of 50Ω may be present in the target battery 210. The short resistance threshold value may be set as 250Ω. Thus, as the estimated short resistance Rₛₕ is less than the short resistance threshold value, a remediation action such as displaying the alert on the display unit 208 is taken.

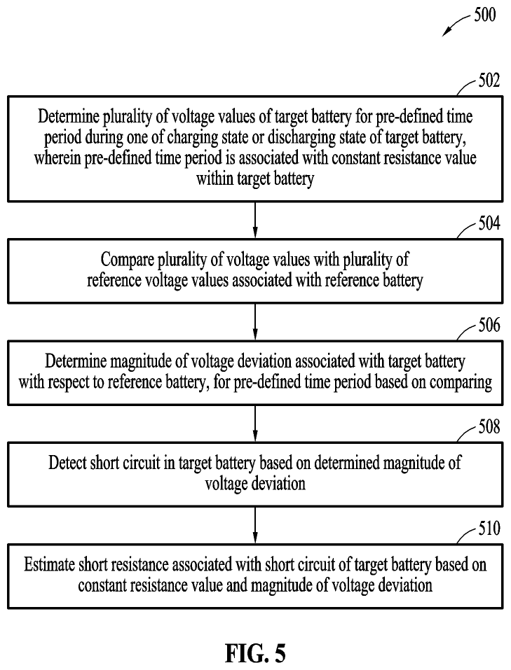

FIG. 5 illustrates an example method 500 of estimating the short resistance of the target battery 210 of the battery-enabled device 200, according to one or more embodiments. In some examples, the method 500 may be performed by the system 216, in particular, the processor 202 in conjunction with the modules 220 and the memory 204.

In operation 502, the method 500 includes determining, when the voltage of the target battery 210 is determined to reach the pre-defined battery voltage, voltage values of the target battery 210 over a pre-defined time period during a charging state (or a discharging state) of the target battery 210. The determining of the voltages may be performed after a preset number of charging cycles and/or upon receiving a user input from a user associated with the battery-enabled device 200. The pre-defined time period may be associated with a constant resistance value within the target battery 210.

In operation 504, the method 500 includes comparing the voltage values from operation 502 with reference voltage values associated with a reference battery.

In operation 506, the method 500 includes determining a magnitude of a voltage deviation associated with the target battery 210 with respect to the reference battery, for the pre-defined time period based on the comparison.

In operation 508, the method 500 includes detecting a short circuit in the target battery 210 based on the determined magnitude of the voltage deviation.

In operation 510, the method 500 includes estimating the short resistance associated with the short circuit of the target battery based on the constant resistance value and the magnitude of the voltage deviation.

Description related to the various operations of FIG. 5 is provided in the description related to FIGS. 2 to 4.

Embodiments and examples described herein may provide technical advantages of effectively detecting the short circuit of the battery 210, and further, effectively estimating the value of a short resistance associated with the short circuit. The relative voltage change during a CR phase is generally associated with a short-circuit linked leakage current. Embodiments and examples described herein may estimate a soft short (e.g., 500Ω) with 90% accuracy during a charging or discharging cycle of the battery. Moreover, there may be no requirement to change or modify the existing charging protocol or hardware, and there may be no need for any special data, or special probes like switching off the device. The pre-defined time period for the CR phase may be minimal, such as 5 minutes or 3 minutes. The computation time is also minimal such as <1 ms with <1 kB data.

Referring to FIG. 6, an example implementation of a hardware configuration of the battery-enabled device 200 is illustrated in the form of a computer device 600. The computer device 600 may include a set of instructions that are executable to cause the computer device 600 to perform any one or more of the methods disclosed. The computer device 600 may operate as a standalone device or may be connected, e.g., using a network, to other computer systems or peripheral devices.

In a networked deployment, the computer device 600 may operate in the capacity of a server or as a client-user computer in a server-client user network environment, or as a peer computer system in a peer-to-peer (or distributed) network environment. The computer device 600 may also be implemented as or incorporated across various devices, such as a personal computer (PC), a tablet PC, a personal digital assistant (PDA), a mobile device, a palmtop computer, a laptop computer, a desktop computer, a communications device, a wireless telephone, a land-line telephone, a web appliance, a network router, switch or bridge, or any other machine capable of executing a set of instructions (sequential or otherwise) that specify actions to be taken by that machine. Further, while a single computer device 600 is illustrated, the term “system” shall also be taken to include any collection of systems or sub-systems that individually or jointly execute a set, or multiple sets, of instructions to perform one or more computer functions.

The computer device 600 may include a processor 602, for example, a central processing unit (CPU), a graphics processing unit (GPU), or both. The processor 602 may correspond to the processor 202 of the battery-enabled device 200. The processor 602 may be a component in a variety of systems. As an example, the processor 602 may be part of a standard personal computer or a workstation. The processor 602 may be one or more general processors, digital signal processors, application-specific integrated circuits, field-programmable gate arrays, servers, networks, digital circuits, analog circuits, combinations thereof, or other now known or later developed devices for analyzing and processing data. The processor 602 may implement a software program, such as code/instructions generated manually (i.e., programmed).

The computer device 600 may include a memory 604, such as a memory that may communicate via a bus 608. The memory 604 may correspond to the memory 204 of the battery-enabled device 200. The memory 604 may include, but is not limited to, computer-readable storage media such as various types of volatile and non-volatile storage media, including, but not limited to, random-access memory, read-only memory, programmable read-only memory, electrically programmable read-only memory, electrically erasable read-only memory, flash memory, magnetic tape or disk, optical media, and the like. In an example, the memory 604 includes a cache or random-access memory for the processor 602. In an alternative example, the memory 604 is separate from the processor 602, such as a cache memory of a processor, the system memory, or other memory. The memory 604 may be an external storage device or database for storing data. The memory 604 is operable to store instructions executable by the processor 602. The functions, acts, or tasks illustrated in the figures or described may be performed by the programmed processor 602 for executing the instructions stored in the memory 604. The functions, acts, or tasks are independent of the particular type of instruction set, storage media, processor, or processing strategy and may be performed by software, hardware, integrated circuits, firmware, micro-code, and the like, operating alone or in combination. Likewise, processing strategies may include multiprocessing, multitasking, parallel processing, and the like.

As shown, the computer device 600 may or may not further include the display 610, such as a liquid crystal display (LCD), an organic light-emitting diode (OLED), a flat panel display, a solid-state display, a projector, a printer or other now known or later developed display devices for outputting determined information. The display 610 may act as an interface for a user to see the functioning of the processor 602, or specifically as an interface with the software stored in the memory 604 or a drive unit 606.

Additionally, the computer device 600 may include an input device 612 configured to allow the user to interact with any of the components of the computer device 600. The computer device 600 may also include a drive unit (disk or optical drive unit) 606. The drive unit 606 may include a computer-readable medium 620 in which one or more sets of instructions 618, for example, software, may be embedded. Further, the instructions 618 may embody one or more of the methods or logic as described. In a particular example, the instructions 618 may reside completely, or at least partially, within the memory 604 or the processor 602 during the execution by the computer device 600.

The present disclosure contemplates a computer-readable medium (not a signal per se) that includes the instructions 618 or receives and executes the instructions 618 so that a device connected to a network 616 may communicate voice, video, audio, and images or any other data over the network 616. Further, the instructions 618 may be transmitted or received over the network 616 via a communication port (or the communication interface) 614 or using the bus 608. The communication port (or the communication interface) 614 may be part of the processor 602 or may be a separate component. The communication port (or the communication interface) 614 may be generated in software or may be a physical connection in hardware. The communication port (or the communication interface) 614 may be configured to connect with the network 616, external media, the display 610, or any other components in the computer device 600, or combinations thereof. The connection with the network 616 may be a physical connection, such as a wired Ethernet connection, or may be established wirelessly as discussed later. Likewise, the additional connections with other components of the computer device 600 may be physical or may be established wirelessly. The network 616 may alternatively be directly connected to the bus 608.

The network 616 may include wired networks, wireless networks, Ethernet AVB networks, or combinations thereof. The wireless network may be a cellular telephone network, an 802.11, 802.16, 802.20, 802.1Q, or WiMax network, etc. Further, the network 616 may be a public network, such as the Internet, a private network, such as an intranet, or combinations thereof, and may utilize a variety of networking protocols now available or later developed including, but not limited to, TCP/IP-based networking protocols. The system is not limited to an operation with any particular standards and protocols. As an example, standards for Internet and other packet-switched network transmissions (e.g., TCP/IP, UDP/IP, HTML, and HTTP) may be used.

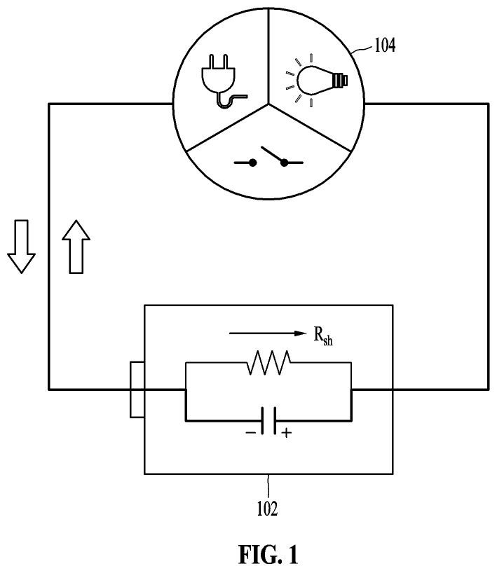

The computing apparatuses, the electronic devices, the processors, the memories, the displays, the information output system and hardware, the storage devices, and other apparatuses, devices, units, modules, and components described herein with respect to FIGS. 1-6 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-6 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A method of estimating a short resistance of a target battery configured to provide power to a device, the method performed by one or more processors, the method comprising:
determining voltage values of the target battery within a time period during a charging or discharging state of the target battery, wherein the time period is associated with a constant resistance value within the target battery;
comparing the voltage values with reference voltage values associated with a reference battery;
based on the comparing, determining, for the time period, a magnitude of a voltage deviation of the target battery with respect to the reference battery;
detecting a short circuit in the target battery based on the determined magnitude of the voltage deviation; and
estimating the short resistance associated with the short circuit of the target battery based on the constant resistance value and the magnitude of the voltage deviation.

2. The method of claim 1, wherein the determining of the magnitude of the voltage deviation comprises:
determining a first curve based on the voltage values determined within the time period;
obtaining a second curve based on the reference voltage values associated with the reference battery; and
calculating the magnitude of the voltage deviation based on a comparison of the first curve with the second curve.

3. The method of claim 2, wherein the detecting of the short circuit in the target battery comprises:
comparing the magnitude of the voltage deviation with a voltage threshold value; and
based on determining that the magnitude of the voltage deviation is greater than the voltage threshold value, detecting the short circuit in the target battery.

4. The method of claim 1, wherein the short resistance is proportional to a ratio of the magnitude of the voltage deviation and the constant resistance value.

5. The method of claim 1, wherein the determining of the voltage values comprises:
determining a current voltage of the target battery; and
determining the voltage values within the time period based on the current voltage reaching a pre-defined battery voltage.

6. The method of claim 1, wherein
the time period is associated with timestamps,
each voltage value corresponds to a product of a total resistance and a total current within the target battery at a time of a corresponding timestamp, and
each reference voltage value corresponds to a product of a total resistance and a total current within the reference battery at a time of a corresponding timestamp.

7. The method of claim 1, wherein the target battery comprises, or is comprised in, a rechargeable lithium-ion (Li-ion) battery.

8. The method of claim 1, further comprising:
comparing the estimated short resistance with a short resistance threshold value; and
based on determining that the estimated short resistance is less than the short resistance threshold value, initiating a remediation action.

9. The method of claim 8, wherein the remediation action comprises rendering an alert or controlling use of the battery.

10. The method of claim 1, wherein the estimating of the short resistance comprises calculating, using an electrochemical-thermal model, the short resistance utilizing the constant resistance value and the magnitude of the voltage deviation of the voltage values with respect to the reference voltage values.

11. The method of claim 1, wherein the constant resistance value, the time period, and the reference voltage values are pre-stored in a memory associated with the battery-enabled device.

12. A system for estimating a short resistance of a target battery, the system comprising:
one or more processors;
memory storing instructions configured to cause the one or more processors to:
determine voltage values of the target battery for a time period during a charging or discharging state of the target battery, wherein the time period is associated with a constant resistance value within the target battery;
compare the voltage values with reference voltage values associated with a reference battery, and
based on the comparing, for the time period, determine a magnitude of a voltage deviation of the target battery with respect to the reference battery;
detect a short circuit in the target battery based on the determined magnitude of the voltage deviation; and
estimate the short resistance of the target battery based on the constant resistance value and the magnitude of the voltage deviation.

13. The system of claim 12, wherein the instructions are further configured to cause the one or more processors to:
determine a first curve based on the voltage values determined within the time period,
obtain a second curve based on the reference voltage values associated with the reference battery, and
calculate the magnitude of the voltage deviation based on a comparison of the first curve with the second curve.

14. The system of claim 13, wherein the instructions are further configured to cause the one or more processors:
compare the magnitude of the voltage deviation with a voltage threshold value, and
based on determining that the magnitude of the voltage deviation is greater than the voltage threshold value, detect the short circuit in the target battery.

15. The system of claim 11, wherein the instructions are further configured to cause the one or more processors to:
determine a current voltage associated with the target battery, and
determine the voltage values for the time period when the current voltage reaches a pre-defined battery voltage.

16. The system of claim 11, wherein
the time period is associated with timestamps,
each voltage value corresponds to a product of a total resistance and a total current within the target battery at a time of a corresponding timestamp, and
each reference voltage value corresponds to a product of a total resistance and a total current within the reference battery at a time of a corresponding timestamp.

17. The system of claim 11, wherein the target battery comprises, or is comprised in, a rechargeable lithium-ion (Li-ion) battery.

18. The system of claim 11, wherein the instructions are further configured to cause the one or more processors to:
compare the estimated short resistance with a short resistance threshold value, and
based on determining that the estimated short resistance is less than the short resistance threshold value, display an alert on a display unit of the battery-enabled device.

19. The system of claim 11, wherein the instructions are further configured to cause the one or more processors to calculate, using an electrochemical-thermal model, the short resistance utilizing the constant resistance value and the magnitude of the voltage deviation in the voltage values with respect to the reference voltage values.

20. A battery-enabled device comprising:
a memory; and
a processor communicatively coupled with the memory,
wherein the processor is configured to:
determine voltage values of a target battery for a defined time period, having a constant resistance value within the target battery,
obtain reference voltage values corresponding to the defined time period, the reference voltages associated with a reference battery,
determine a magnitude of a voltage deviation between the voltage values and the reference voltage values,
detect a short circuit in the target battery based on the determined magnitude of the voltage deviation, and
estimate a short resistance of the target battery based on the constant resistance value and the magnitude of the voltage deviation.
